(19) United States
(12) Patent Application Publication
(10) Pub. No.: US 2023/0232546 A1
(43) Pub. Date: Jul. 20, 2023

(54) MANUFACTURING PROCESS OF RIGID-FLEX BOARD

(71) Applicants: CHIA-MING LI, New Taipei City (TW); Guangdong ZECHENG Technology Co., LTD, Guangdong Province (CN)

(72) Inventor: CHIA-MING LI, New Taipei City (TW)

(21) Appl. No.: 17/738,913

(22) Filed: May 6, 2022

(30) Foreign Application Priority Data
Jan. 17, 2022 (TW) 111101775

(51) Int. Cl. H05K 3/46; H05K 1/14; H05K 3/42

(52) U.S. Cl. CPC H05K 3/4691; H05K 3/4652; H05K 1/147; H05K 3/422

(57) ABSTRACT

A rigid-flex board is manufactured by attaching multiple self-adhesive copper foil films to a flexible circuit board through multiple build-up processes, thereby eliminating the need to pre-fabricate a rigid board and slot the rigid board. The build-up processes of the self-adhesive copper foil films allow the resulting rigid boards to be highly uniform in thickness so that thickness deviation of the rigid-flex board can be reduced.

### BACKGROUND OF THE INVENTION

### 1. Technical Field

The present invention relates to a manufacturing process of a rigid-flex board and more particularly to the technique of manufacturing rigid circuit boards by performing multiple build-up processes on a flexible circuit board that is prepared in advance.

### 2. Description of Related Art

A rigid-flex board is composed essentially of a flexible circuit board (also referred to herein as a flexible board) and a rigid circuit board (also referred to herein as a rigid board) and is often used as a carrier of the components of an electronic product because it provides both the flexibility of the flexible board and the strength of the rigid board.

Conventionally, a rigid-flex board is formed by manufacturing a flexible board and a rigid board separately and then pressing the two boards together, wherein the rigid board is slotted before the pressing operation so that the flexible board can be exposed through the slots after the pressing operation, thereby allowing the slot areas of the resulting rigid-flex board to be flexible and surface-mounted devices to be mounted on the rigid board. The foregoing manufacturing process, however, is both complicated and costly, so it is worthwhile for those working in the technical field to which the present invention pertains to improve the existing technique.

### BRIEF SUMMARY OF THE INVENTION

In view of the above, the primary objective of the present invention is to provide a rigid-flex board manufacturing process that dispenses with pre-fabricating a rigid board, slotting the rigid board, and pressing the slotted rigid board and a flexible board together.

To achieve the foregoing and other objectives, the present invention provides a manufacturing process of a rigid-flex board, wherein the manufacturing process includes manufacturing a flexible circuit board and performing multiple build-up processes on at least one side of the flexible circuit board to form at least two rigid circuit boards on the flexible circuit board, wherein at least one of the build-up processes includes the following steps:

(1) A self-adhesive copper foil film is attached to at least one build-up side of the semi-finished rigid-flex board on which the at least one build-up process is being performed. The self-adhesive copper foil film has a copper foil layer and a B-stage insulating adhesive layer. The insulating adhesive layer is applied on the copper foil layer and does not have glass fiber. The build-up side is in contact with the insulating adhesive layer but not in contact with the copper foil layer. The copper foil layer has a first copper foil area located on a lateral side (hereinafter referred to as the first lateral side) of the semi- finished rigid-flex board, a second copper foil area located on another lateral side (hereinafter referred to as the second lateral side) of the semi-finished rigid-flex board, and an intermediate copper foil area connected between the first and the second copper foil areas, wherein the first and the second copper foil areas are not in contact with each other. The insulating adhesive layer has a first insulating adhesive area located on the first lateral side of the semi-finished rigid-flex board, a second insulating adhesive area located on the second lateral side of the semi-finished rigid-flex board, and an intermediate insulating adhesive area connected between the first and the second insulating adhesive areas, wherein the first and the second insulating adhesive areas are not in contact with each other. The first, the second, and the intermediate insulating adhesive areas are covered by the first, the second, and the intermediate copper foil areas respectively.

(2) The intermediate copper foil area is removed.

(3) The intermediate insulating adhesive area is removed with an etching solution.

(4) The first and the second insulating adhesive areas are completely cured.

By attaching multiple self-adhesive copper foil films to the flexible circuit board through multiple build-up processes, a rigid-flex board can be manufactured without having to pre-fabricate a rigid board and slot the rigid board. The build-up processes of the self-adhesive copper foil films also allow the resulting rigid boards to be highly uniform in thickness so that thickness deviation of the rigid-flex board can be reduced. Moreover, now that rigid boards can be formed by performing multiple build-up processes on a flexible circuit board, the manufacturing process of the present invention provides a higher degree of freedom in electronic product design than the prior art.

### BRIEF DESCRIPTION OF THE SEVERAL VIEWS OF THE DRAWINGS

FIG. 1 to FIG. 11 show the manufacturing process according to one embodiment of the present invention; and

FIG. 12 and FIG. 13 show the manufacturing process according to another embodiment of the invention and demonstrate a different process for forming vias.

### DETAILED DESCRIPTION OF THE INVENTION

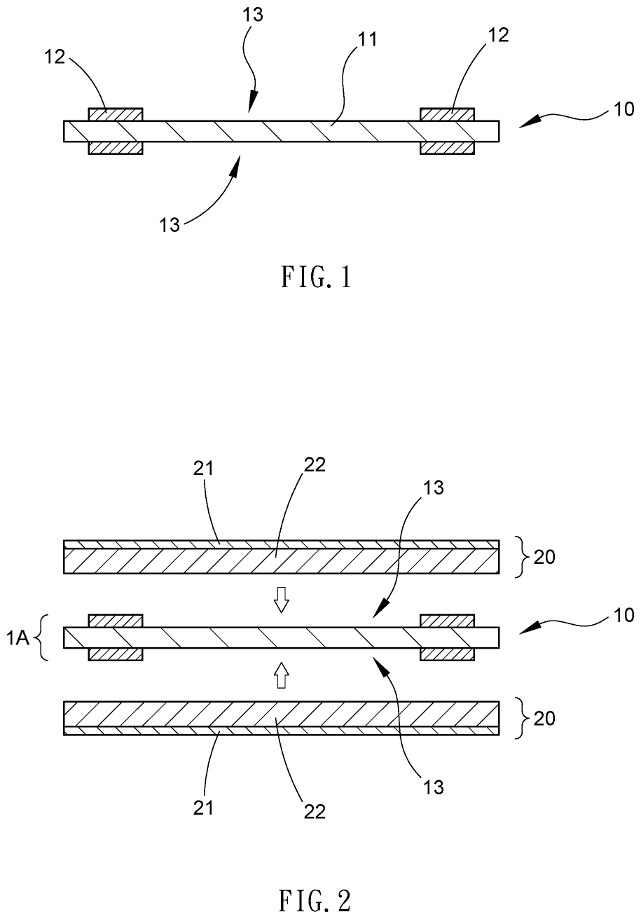

The present invention discloses a manufacturing process of a rigid-flex board. The manufacturing process according to one embodiment of the invention is described below with reference to FIG. 1 to FIG. 11, in which the circuit designs on the flexible board and in/or the rigid boards are simplified to the greatest extent to facilitate description; the actual circuit designs are not limited to those illustrated herein.

Please refer to FIG. 1 for a flexible circuit board 10 that is prepared in advance. The flexible circuit board 10 is flexible and at least includes a dielectric layer 11 and a flexible circuit 12. The flexible circuit board 10 may be manufactured by a conventional method. If rigid circuit boards are to be manufactured on each of the two opposite sides of the flexible circuit board 10, the flexible circuit board 10 will have two build-up sides 13; if rigid circuit boards are to be manufactured on only one side of the flexible circuit board 10, the flexible circuit board 10 will have only one build-up side 13. In this embodiment, the two opposite sides of the flexible circuit board 10 are both build-up sides 13.

Once the flexible circuit board is prepared, multiple build-up processes are sequentially performed on at least one side of the flexible circuit board to form at least two rigid circuit boards on the flexible circuit board. At least one of the build-up processes includes the following steps:

Step (1):

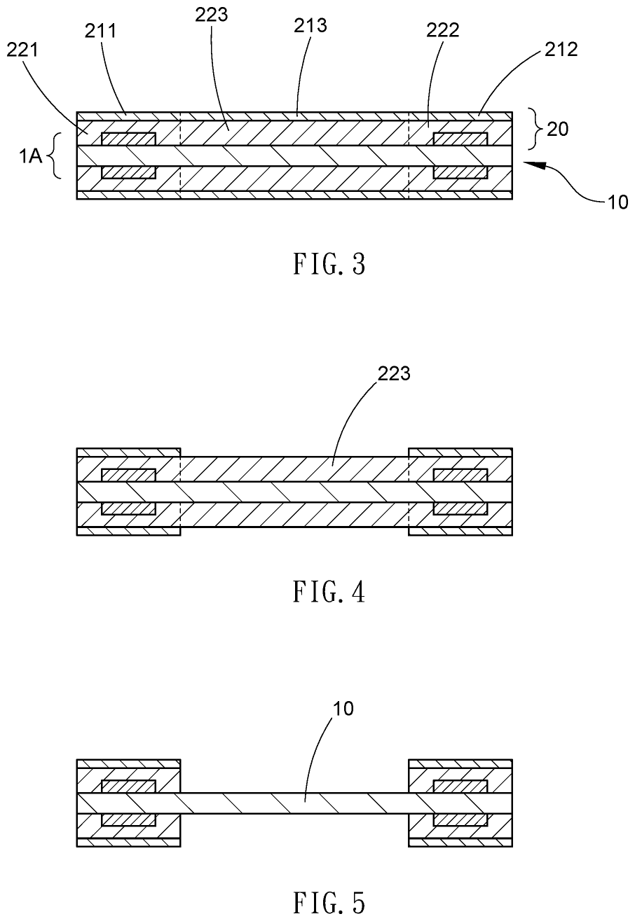

Referring to FIG. 2 and FIG. 3, a self-adhesive copper foil film 20 is attached to each of the two build-up sides 13 of the semi-finished rigid-flex board 1A on which the at least one build-up process is being performed. A “semi-finished rigid-flex board” is in a state that is prior to completion of the rigid-flex board and followed by a subsequent manufacturing step. For example, when the first build-up process is about to be performed on the build-up sides 13 of the flexible circuit board 10, the flexible circuit board 10 itself is the “semi-finished rigid-flex board” at the moment. Each self-adhesive copper foil film 20 has a copper foil layer 21 and a B-stage insulating adhesive layer 22, wherein the insulating adhesive layer 22 is applied on the copper foil layer 21 and does not have glass fiber. Each build-up side 13 is in contact with the corresponding insulating adhesive layer 22 but not in contact with the corresponding copper foil layer 21. The insulating adhesive layers 22 may be, for example, an epoxy-based, acrylic-based, or polyimide-based photocuring and/or heat-curing resin. The term “B-stage” refers to a stage in which a curable resin is not completely cured but has been dried to such an extent that it is dry to the touch of a finger. Depending on its photocuring and/or heat-curing property, a B-stage resin can be completely cured by exposure to light of a specific wavelength and/or a specific curing temperature and thus enter the C stage. In the present invention, the insulating adhesive layers 22 stay in the B stage before step (4). Each copper foil layer 21 has a first copper foil area 211 located on a lateral side (hereinafter referred to as the first lateral side) of the semi-finished rigid-flex board 1A, a second copper foil area 212 located on another lateral side (hereinafter referred to as the second lateral side) of the semi-finished rigid-flex board 1A, and an intermediate copper foil area 213 connected between the first and the second copper foil areas 211 and 212, wherein the first and the second copper foil areas 211 and 212 are not in contact with each other. Each insulating adhesive layer 22 has a first insulating adhesive area 221 located on the first lateral side of the semi-finished rigid-flex board 1A, a second insulating adhesive area 222 located on the second lateral side of the semi-finished rigid-flex board 1A, and an intermediate insulating adhesive area 223 connected between the first and the second insulating adhesive areas 221 and 222, wherein the first and the second insulating adhesive areas 221 and 222 are not in contact with each other. The first, the second, and the intermediate insulating adhesive areas 221, 222, and 223 of each insulating adhesive layer 22 are covered by the first, the second, and the intermediate copper foil areas 211, 212, and 213 of the corresponding copper foil layer 21 respectively.

Step (2):

Referring to FIG. 4, each intermediate copper foil area 213 is removed to expose the corresponding intermediate insulating adhesive area 223. In one feasible embodiment, the intermediate copper foil areas 213 are removed by a conventional method that includes applying a photoresist, exposure to light, development, and etching. The removing method, however, is not limited to the foregoing and may involve laser engraving instead.

Step (3):

Referring to FIG. 5, the intermediate insulating adhesive areas 223 are removed with an etching solution. As used herein, the term “etching solution” refers to a preparation for removing the B-stage insulating adhesive layer in contact therewith. Once the intermediate insulating adhesive areas 223 are removed, a middle portion of the flexible circuit board 10 is exposed, and the flexibility of that middle portion is thus restored.

Step (4):

Depending on their photocuring and/or heat-curing property, the B-stage insulating adhesive layers 20 are exposed to light of a specific wavelength and/or a specific curing temperature until completely cured. The cured insulating adhesive layers 20 are still in the shapes shown in FIG. 5.

Step (5):

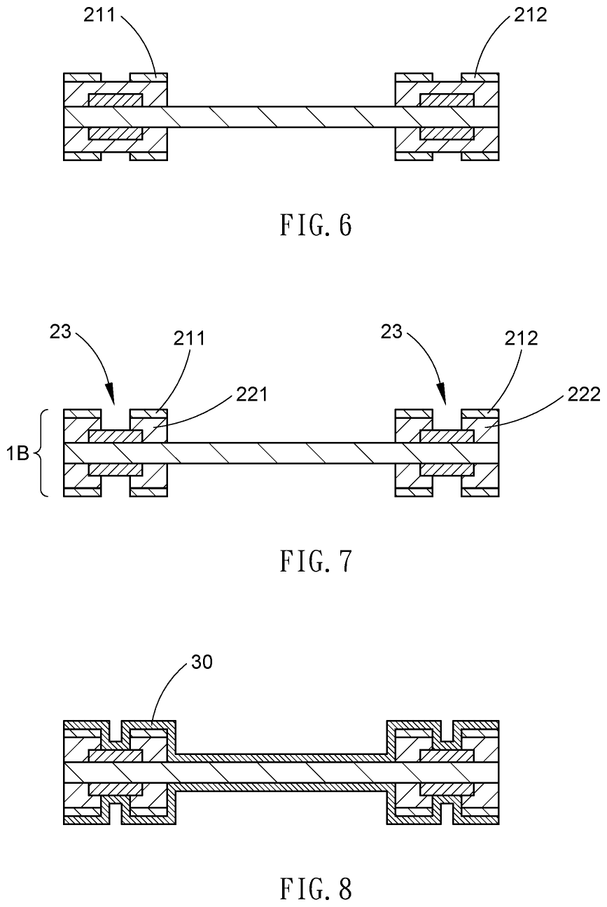

Referring to FIG. 6, a copper window is formed in each first copper foil area 211 and in each second copper foil area 212. After that, referring to FIG. 7, a window is formed in each first insulating adhesive area 221 and in each second insulating adhesive area 222 at a position corresponding to the copper window in the corresponding copper foil area 211/212 such that at least one via 23 is formed in each first copper foil area 211 and the corresponding first insulating adhesive area 221 and in each second copper foil area 212 and the corresponding second insulating adhesive area 222. The copper window/window forming method may be a dry method (e.g., laser engraving) or a wet method (e.g., by way of a chemical).

Step (6):

An electrolessly plated copper layer 30 is formed on each side of the semi-finished rigid-flex board 1B (i.e., the semi-finished product shown in FIG. 7) by electroless plating such that the semi-finished rigid-flex board 1B enters the state shown in FIG. 8.

Step (7):

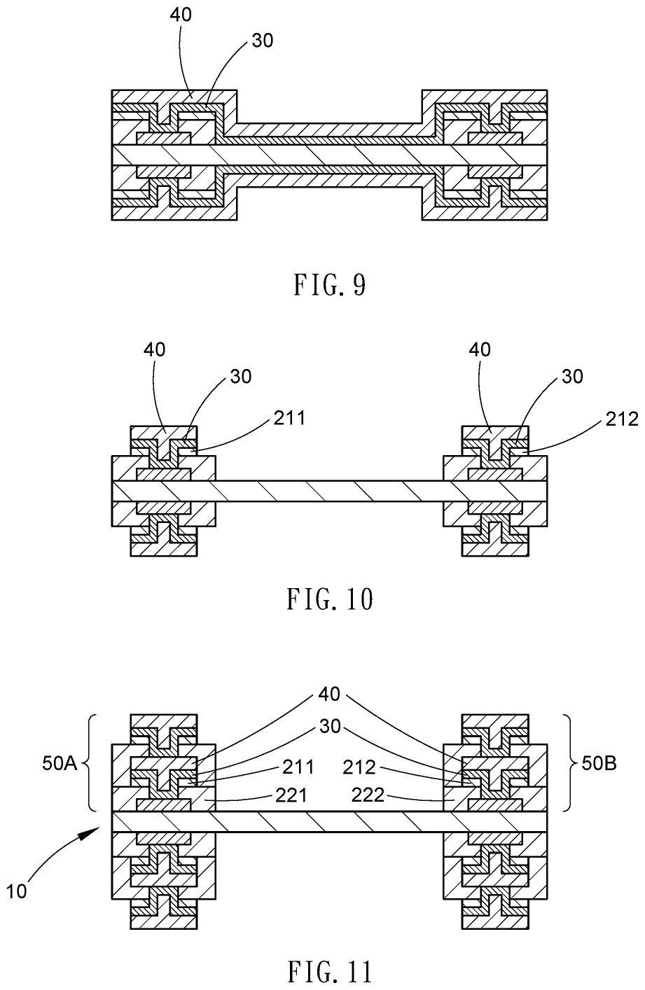

Referring to FIG. 9, an electroplated copper layer 40 is formed on each electrolessly plated copper layer 30 by electroplating.

Referring to FIG. 10, the first and the second copper foil areas 211 and 212, the electrolessly plated copper layers 30, and the electroplated copper layers 40 are subjected to a patterning process to form the desired circuit patterns.

Following that, a second build-up process may be carried out to form the circuit patterns shown in FIG. 11. If the rigid-flex board to be manufactured requires only those two build-up processes, the build-up structures resulting from the two build-up processes as shown in FIG. 11 are the intended rigid circuit boards 50A and 50B. That is to say, the resulting rigid-flex board includes one flexible circuit board 10 and at least two rigid circuit boards 50A and 50B. The rigid circuit boards 50A and 50B are formed on the build-up sides of the flexible circuit board 10 and each have at least one completely cured first/second insulating adhesive area 221/222 (i.e., an insulating adhesive area), a first/second copper foil area 211/212 (i.e., a copper foil area) covering the insulating adhesive area, an electrolessly plated copper layer 30 covering the copper foil area, and an electroplated copper layer 40 covering the electrolessly plated copper layer 30, wherein the insulating adhesive area does not have glass fiber.

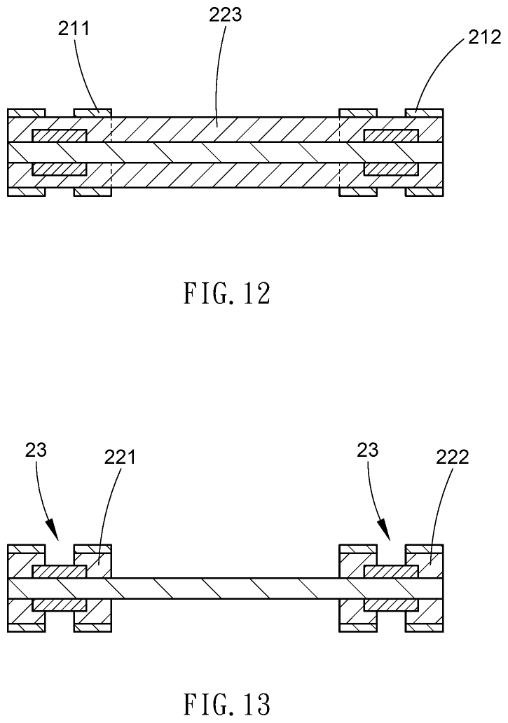

In the embodiment described above, the vias 23 are formed after step (4). In the embodiment shown in FIG. 12 and FIG. 13, the vias 23 are formed before step (4) instead. More specifically, referring to FIG. 12, a copper window is formed in each first copper foil area 211 and in each second copper foil area 212 while step (2) is performed to remove the intermediate copper foil areas 213. Then, in the course in which the intermediate insulating adhesive areas 223 are removed, a window is formed in each first insulating adhesive area 221 and in each second insulating adhesive area 222 with the etching solution used to remove the intermediate insulating adhesive areas 223, as shown in FIG. 13, and only after that are the first and the second insulating adhesive areas 221 and 222 completely cured to form the vias 23.

What is claimed is:

1. A manufacturing process of a rigid-flex board, comprising: manufacturing a flexible circuit board; and performing multiple build-up processes on at least one side of the flexible circuit board to form at least two rigid circuit boards on the flexible circuit board, wherein at least one of the build-up processes comprises the steps of:
(1) attaching a self-adhesive copper foil film to at least one build-up side of a semi-finished rigid-flex board on which the at least one build-up process is being performed, wherein the self-adhesive copper foil film has a copper foil layer and a B-stage insulating adhesive layer, the insulating adhesive layer is applied on the copper foil layer, the insulating adhesive layer does not have glass fiber, the build-up side is in contact with the insulating adhesive layer but not in contact with the copper foil layer, the copper foil layer has a first copper foil area located on a first lateral side of the semi-finished rigid-flex board, a second copper foil area located on a second lateral side of the semi-finished rigid-flex board, and an intermediate copper foil area connected between the first copper foil area and the second copper foil area, the first copper foil area and the second copper foil area are not in contact with each other, the insulating adhesive layer has a first insulating adhesive area located on the first lateral side of the semi-finished rigid-flex board, a second insulating adhesive area located on the second lateral side of the semi-finished rigid- flex board, and an intermediate insulating adhesive area connected between the first insulating adhesive area and the second insulating adhesive area, the first insulating adhesive area and the second insulating adhesive area are not in contact with each other, and the first insulating adhesive area, the second insulating adhesive area, and the intermediate insulating adhesive area are covered by the first copper foil area, the second copper foil area, and the intermediate copper foil area respectively;
(2) removing the intermediate copper foil area;
(3) removing the intermediate insulating adhesive area with an etching solution; and
(4) curing the first insulating adhesive area and the second insulating adhesive area completely.

2. The manufacturing process of a rigid-flex board as claimed in claim 1, further comprising the steps, to be performed after the step (4), of:
(5) forming at least one via in the first copper foil area and the first insulating adhesive area and in the second copper foil area and the second insulating adhesive area;
(6) forming an electrolessly plated copper layer on the semi-finished rigid-flex board by electroless plating;
(7) forming an electroplated copper layer on the electrolessly plated copper layer by electroplating; and
(8) patterning the first copper foil area, the second copper foil area, the electrolessly plated copper layer, and the electroplated copper layer.
